(19) United States
(12) Patent Application Publication
(10) Pub. No.: US 2012/0063069 A1
(43) Pub. Date: Mar. 15, 2012

(54) PLASMA DISPLAY APPARATUS

(75) Inventor: Joon-mok HAN, Suwon-si (KR)

(73) Assignee: SAMSUNG ELECTRONICS CO., LTD., Suwon-si (KR)

(21) Appl. No.: 13/037,828

(22) Filed: Mar. 1, 2011

(30) Foreign Application Priority Data
Sep. 9, 2010 (KR) 2010-0088548

(51) Int. Cl. H05K 7/00

(52) U.S. Cl. 361/679.01

(57) ABSTRACT

A plasma display apparatus is provided, which includes a plasma display panel, a chassis base which supports the plasma display panel, a driving board which is electrically connected to the plasma display panel and arranged on the chassis base, and which supplies a driving signal to the plasma display panel, and a back cover which covers the plasma display panel, wherein the back cover is connected to a ground area of the driving board.

### CROSS-REFERENCE TO RELATED APPLICATIONS

This application claims priority from Korean Patent Application No. 10-2010-0088548, filed on Sep. 9, 2010, in the Korean Intellectual Property Office, the disclosure of which is incorporated herein by reference in its entirety.

### BACKGROUND

1. Field of the Invention

Apparatuses consistent with the exemplary embodiments provided herein relate to a plasma display apparatus, and more particularly, to a plasma display apparatus capable of suppressing sustain noise.

2. Description of the Related Art

Recently, flat screen displays such as liquid crystal displays (LCD), field emission displays (FED), or plasma display apparatuses have been actively developed.

Among these, the plasma displays provide advantages such as higher brightness and luminous efficacy and wider viewing angle. Due to these advantages, the plasma displays have been gaining popularity as the replacement for conventional cathode ray tube (CRT) particularly in the field of large screen displays exceeding 40 inches in size.

As one type of flat screen display, the plasma display displays images thereon using plasma which is generated by the discharge of gas. Depending on size, from several tens to several tens of thousand pixels are arranged in the form of a matrix.

Meanwhile, the plasma display, being driven by high frequency and high voltage electric signals, generates electro magnetic interference (EMI). Since the generated EMI interferes with the other electronic apparatuses, it is necessary to control the EMI under a predetermined reference.

It is also necessary to consider the noise which can be generated during driving of the respective pixels of the plasma display, since the noise can generate EMI-related problems.

### SUMMARY

Exemplary embodiments of the present inventive concept overcome the above disadvantages and other disadvantages not described above. Also, the present inventive concept is not required to overcome the disadvantages described above, and an exemplary embodiment of the present inventive concept may not overcome any of the problems described above.

According to one exemplary embodiment, a plasma display apparatus is provided, in which a ground area of a driving board is connected to a back cover, so that noise generated during driving of pixels is dissipated.

In one exemplary embodiment, a plasma display apparatus may be provided, including a plasma display panel, a chassis base which supports the plasma display panel, a driving board which is electrically connected to the plasma display panel and arranged on the chassis base, and which supplies a driving signal to the plasma display panel, a device unit attached to the driving board to generate the driving signal, and a back cover which covers the plasma display panel, wherein the back cover is connected to a ground area of the driving board.

The plasma display apparatus may additionally include a conductive material attached to one side of the back cover.

The back cover may be connected to the ground area via the conductive material.

The plasma display apparatus may additionally include a heat sink arranged in contact with the device unit to transfer heat generated from the device unit to outside.

The back cover may be connected to the heat sink via the conductive material and the heat sink may be connected to the ground area.

The driving board may be arranged on one side of the chassis base and the plasma display panel may be arranged on the other side of the chassis base.

The driving board may be a Y driving board.

The device unit may include one or more switching devices, and the one or more switching devices may include a ground pin connected to the ground area of the driving board.

The one or more switching devices may include an integrated circuit (IC).

The one or more switching elements may include a Yg switching IC.

The plasma display apparatus may additionally include an alternating current (AC) inlet which is attached to one side of the chassis base and receives electricity through a power cable, and a switched mode power supply (SMPS) unit which is attached to one side of the chassis base and which converts the received electricity and provides the converted electricity to the plasma display panel.

The plasma display apparatus may dissipate induced sustain noise to the back cover, the chassis base, the AC inlet and the SMPS unit, respectively.

### BRIEF DESCRIPTION OF THE DRAWINGS

The above and/or other aspects of the present inventive concept will be more apparent by describing certain exemplary embodiments of the present inventive concept with reference to the accompanying drawings, in which:

FIG. 1 is a schematic view of a plasma display apparatus according to an exemplary embodiment;

FIG. 2 is a view provided to explain the plasma display apparatus of FIG. 1 in greater detail;

FIG. 3 is a view provided to explain a driving board of the plasma display apparatus in greater detail;

FIG. 4 is a view provided to explain a back cover of the plasma display apparatus in greater detail;

FIG. 5 is a view illustrating an example of a connecting structure of the plasma display apparatus;

FIG. 6 is a view illustrating another example of the connecting structure of the plasma display apparatus; and

FIG. 7A is a graphical representation of noise generated from a conventional plasma display apparatus, and FIG. 7B is a graphical representation of noise generated from the plasma display apparatus according to an exemplary embodiment.

### DETAILED DESCRIPTION OF EXEMPLARY EMBODIMENTS

Certain exemplary embodiments of the present inventive concept will now be described in greater detail with reference to the accompanying drawings.

In the following description, same drawing reference numerals are used for the same elements even in different drawings. The matters defined in the description, such as detailed construction and elements, are provided to assist in a comprehensive understanding of the present inventive concept. Accordingly, it is apparent that the exemplary embodiments of the present inventive concept can be carried out without those specifically defined matters. Also, well-known functions or constructions are not described in detail since they would obscure the exemplary embodiments with unnecessary detail.

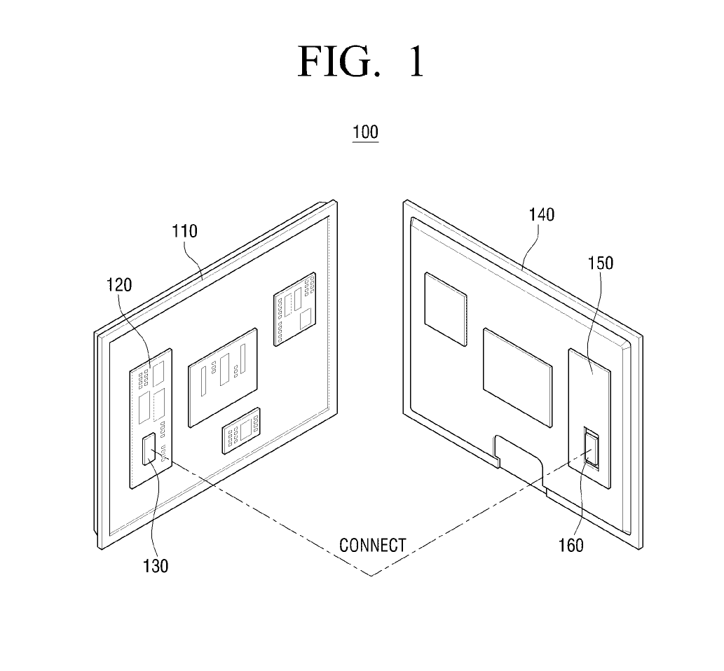

FIG. 1 is a schematic view of a plasma display apparatus according to an exemplary embodiment.

Referring to FIG. 1, the relationship in which the respective components of the plasma display apparatus 100 are connected to each other will be explained briefly, and the operations and functions of the plasma display apparatus 100 will be explained in further detail below with reference to the accompanying drawings according to various exemplary embodiments.

Referring to FIG. 1, a driving board 120 is attached to one side of a chassis base 110, and a heat sink 130, contacting one or more devices (not illustrated) of the driving board 120, may be attached to the driving board 120.

The chassis base 110 supports a plasma display panel (not illustrated), and the plasma display panel (not illustrated) may be arranged on the other side of the chassis base 110.

A back cover 140 covers a rear surface (i.e., a surface facing one side of the chassis base 110) of the plasma display panel (not illustrated).

An insulating material 150 may be attached to the back cover 140 to prevent direct contact (connect) between the one or more devices of the driving board 120 and the back cover 140. The insulating material 150 may be partially removed and a conductive material 160 may be attached to the area from which the insulating material 150 is removed.

When the back cover 140 and the chassis base 110 are assembled with each other to form an integrated structure, the heat sink 130 may be connected to the back cover 140 through the conductive material 160.

Accordingly, the ground area of the driving board 120 can be connected to the back cover 140 via the heat sink 130 and the conductive material 160 to thus cause noise to dissipate when the noise is generated during the driving of the driving board 120 of the plasma display apparatus 100. As a result, the plasma display apparatus 100 can reduce EMI.

The ‘noise’ herein may be represented as the EMI.

Additionally, the phrase that the ‘ground area of the driving board is connected to the back cover’ includes both indirect connection of the ground area to the back cover via another component, and direct connection of the ground area to the back cover.

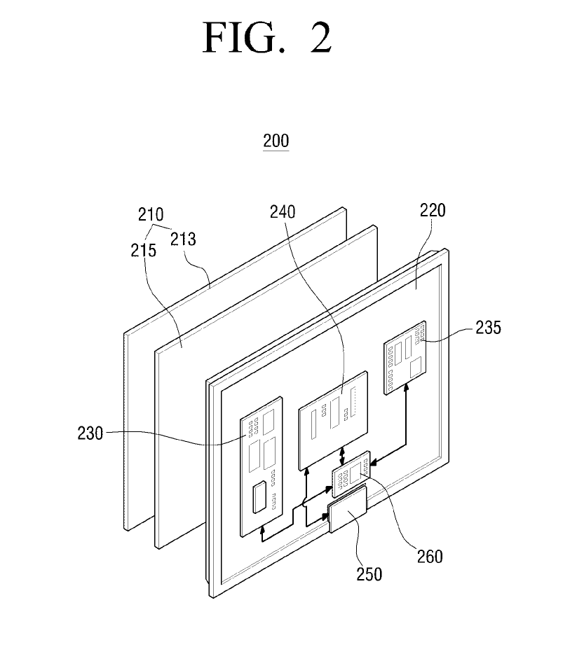

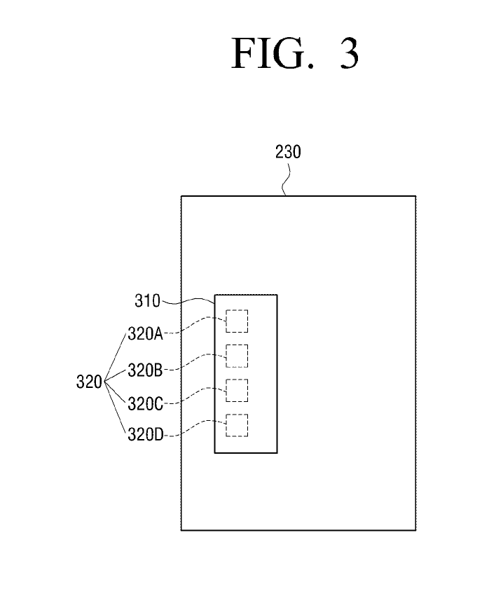

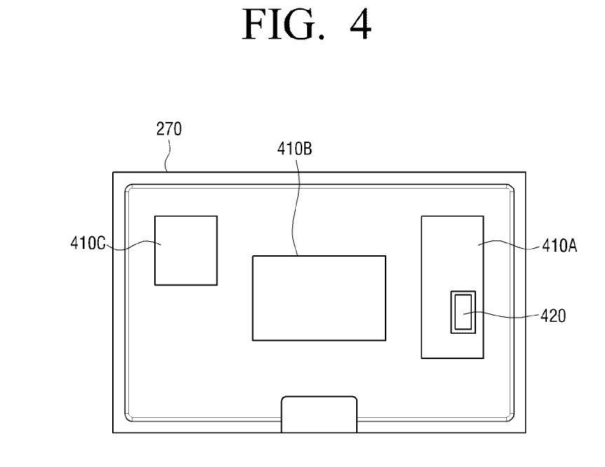

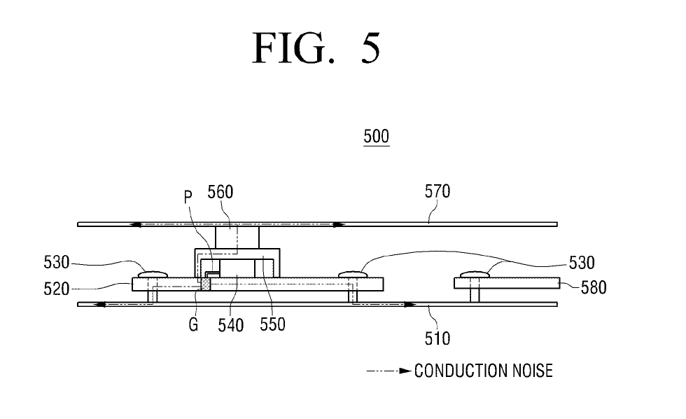

FIG. 2 is a view provided to explain the plasma display apparatus of FIG. 1 in more detail, FIG. 3 is a view provided to explain a driving board of the plasma display apparatus in greater detail, and FIG. 4 is a view provided to explain a back cover of the plasma display apparatus in greater detail. The plasma display apparatus according to an exemplary embodiment will be explained in greater detail with reference to FIGS. 2 to 4 collectively.

Referring to FIGS. 2 to 4, the plasma display apparatus 200 includes a plasma display panel 210, a chassis base 220, driving boards 230, 235, a SMPS unit 240, an AC inlet 250, and a control unit 260.

The plasma display panel 210 includes a front board 213 and a rear board 215. A plurality of discharging spaces, defined by partitions, are formed between the front and rear boards 213, 215, and address electrodes and driving electrodes are arranged across each other in the discharging spaces. In response to a driving signal applied between the address electrodes and the driving electrodes, gas is discharged in the discharging spaces, and a visual light ray is irradiated from the discharging spaces in a direction toward the front board 213 to cause an image to be displayed on the plasma display panel 210.

The chassis base 220 is arranged on the rear board 215 of the plasma display panel 210, and supports the plasma display panel 210. To be specific, the plasma display panel 210 is arranged on the other side of the chassis base 220, and driving boards 230, 235 may be arranged on one side of the chassis base 220.

The chassis base 220 may be made from a conductive material such as metal.

The driving board 230 drives Y electrodes, and the other driving board 235 drives X electrodes. Both of the driving boards 230, 235 may be attached to the chassis base 220.

The driving board 230 is electrically connected to the plasma display panel 210, arranged on the chassis base 220, and supplies a driving signal to the plasma display panel 210. The driving board 230 may be formed in a variety of patterns, and various devices may be attached to the driving board 230. The driving board 230 may include the ground area.

The SMPS unit 240 is attached to one side of the chassis base 220, and converts incoming electricity, and provides converted electricity to at least one of the plasma display panel 210, driving boards 230, 235 and control unit 260.

The SMPS unit 240 receives AC voltage from the AC inlet 250, converts the inputted AC voltage into DC voltage in a first area, and re-converts the once-converted DC voltage to a DC voltage of a predetermined value such as 5V or 12V in a second area.

The AC inlet 250 is attached to one side of the chassis base 220, and receives electricity via an external cable. The AC inlet 250 may provide the electricity to the SMPS unit 240.

The control unit 260 may control the overall operations of the components 210, 230, 235, 240, 250 of the plasma display apparatus 200.

FIG. 3 is a view provided to explain the driving board of the plasma display apparatus in more detail.

Devices 320A, 320B, 320C, 320D (320) may be attached to the driving board 230. That is, the devices 320 are attached to the driving board 230 and generate driving signals. The devices 320 attached on the driving board 230 may form a device unit. Although it is explained above that the four devices are attached to the driving board 230, this is written only for the illustrative purpose. Accordingly, the number of devices 320 is not limited to the above specific example only.

The devices 320 may perform various functions, and include a switching device. The switching device may be implemented as an integrated circuit (IC).

By way of example, the devices 320 may include Yr switching IC, Ys switching IC, Yf switching IC and Yg switching IC.

The Yr switching IC generates a signal to increase a signal value of the signal applied to a Y electrode, Ys switching IC generates a signal to maintain a signal value of the signal applied to the Y electrode, Yf switching IC generates a signal to decrease a signal value of the signal applied to the Y electrode, and Yg switching IC generates a signal to set the signal value of the signal applied to the Y electrode to 0.

The heat sink 310 may be attached to the driving board 230 to contact the devices 320 and transfer heat generated from the devices 320 to outside.

As a result, according to the plasma display apparatus 200 according to an exemplary embodiment, since the heat sink 310 is connected to the back cover 270 and the ground area of the driving board 230 is connected to the back cover 270 through the heat sink 310 and the conductive material 160, noise is reduced.

Meanwhile, the heat sink 310 to be connected to the back cover 270 of the plasma display apparatus 200 may desirably contact the Ys switching IC or Yg switching IC. Particularly, in order to reduce sustain noise which gives the highest influence on EMI, it is desirable to connect the heat sink 310 contacting the Yg switching IC to the back cover 270 of the plasma display apparatus 200 according to an exemplary embodiment.

The heat sink 310 may cause the sustain noise to dissipate to the back cover 270, the AC inlet 250 and the SMPS unit 240, respectively.

FIG. 4 is a view provided to explain the back cover of the plasma display apparatus in more detail.

Referring to FIG. 4, the back cover 270 may cover the plasma display panel 210. The back cover 270 may desirably be made from a conductive material such as metal.

Insulating members 410A, 410B, 410C may be attached to one side of the back cover 270.

If the back cover 270 is in assembled state in which the back cover 270 covers the rear side of the plasma display panel 210, the insulating members 410A, 410B, 410C may directly contact the driving board 230, the SMPS unit 240 and the driving board 235 respectively, or be kept at a predetermined distance from the driving board 230, the SMPS unit 240 and the driving board 235 respectively. As a result, the possible malfunction of the driving board 230, the SMPS unit 240 and the driving board 235, which may occur due to the back cover 270 made from conductive material, is prevented.

In order to reduce noise generated from the plasma display apparatus 200, a part of the insulating member 410A is removed, and a conductive material 420 is attached to the area from which the insulating member 410A is removed, so that the attached conductive material 420 is contacted with the driving board 235.

The conductive material 420 may be a gasket, and the ‘gasket’ herein may collectively refer to various types of conductive materials including cloth, sponge, or the like.

The conductive material 420 may be attached to the area from which a part of the insulating member 410A is removed, so that the attached conductive material 420 contacts the driving board 230. As a result, it is possible to further reduce the sustain noise, and EMI reduction effect is improved.

According to the plasma display apparatus 200, noise is reduced greatly when the heat sink 310, contacting the Yg switching IC and transferring heat to outside, contacts the back cover 270. It is also desirable that the Yg switching IC is attached to the driving board 230, i.e., to the Y driving board to drive the Y electrode.

With the plasma display apparatus 200 according to an exemplary embodiment, the heat sink 310 and the back cover 270 may be connected to each other using the conductive material 420 such as gasket. In such example, the insulating member 410A may not be provided. Additionally, the heat sink 310 and the conductive material 420 may be connected to each other directly.

With the plasma display apparatus 200 according to an exemplary embodiment, the EMI is reduced effectively, without having to use a glass filter as a conductive layer.

Meanwhile, although it has been explained so far that the plasma display apparatuses 100, 200 include the heat sinks 130, 310 and the heat sinks 130, 310 are connected to the back cover 140, 270, this was written only for illustrative purpose. Accordingly, other examples are possible. For example, the heat sinks 130, 310 may not be included, in which case the ground areas of the driving boards 120, 230, 235 can be connected to the back cover 140, 270 through the conductive materials 160, 420.

FIG. 5 is a view provided to explain an example of a connecting structure of the plasma display apparatus according to an exemplary embodiment.

Referring to FIG. 5, the plasma display apparatus 500 is formed such that a driving board 520 is arranged on one side of a chassis base 510. The driving board 520 is attached to one side of the chassis base 510 through at least one screw 530. A variety of patterns may be formed on one side of the driving board 520 and various devices are attached thereto. The driving board 520 includes a ground area G.

Yg switching IC 540 is attached to one side of the driving board 520, and a ground pin (P), from among a plurality of pins (terminals) of Yg switching IC 540, is connected to the ground area G of the driving board 520.

The heat sink 550 is attached to one side of the driving board 520 to contact one side of the Yg switching IC 540. The heat sink 550 may contact the ground area G and arranged to adjoin the ground area G.

A conductive material 560 may be arranged on one side of the heat sink 550, and the conductive material 560 is connected to the back cover 570.

With the plasma display apparatus 500 according to an exemplary embodiment, since the ground area G of the driving board 520 is connected to the back cover 570 via the heat sink 550 and the conductive material 560, conduction noise dissipates and as a result, EMI is reduced.

The term ‘one side’ in FIG. 5 refers to upper sides of the respective components 510, 520, 540, 550. The component 580 in FIG. 5 may be the AC inlet or SMPS unit. Referring also to FIG. 5, although the exemplary embodiment has been explained mainly with reference to Yg switching IC 540 which has the greatest EMI reduction effect among the various other devices, the exemplary embodiment is not limited to this specific example only.

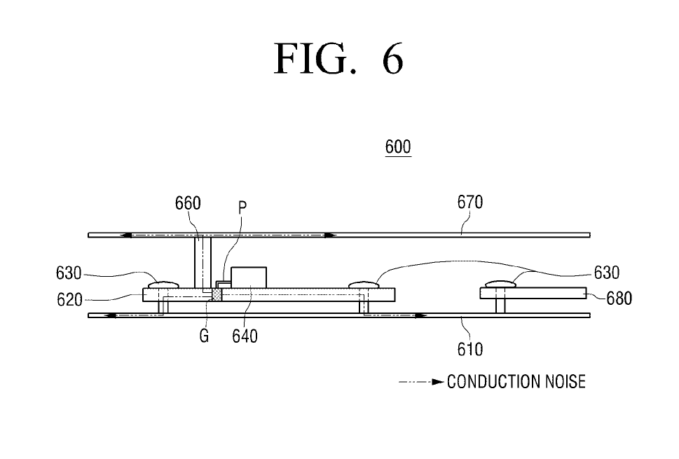

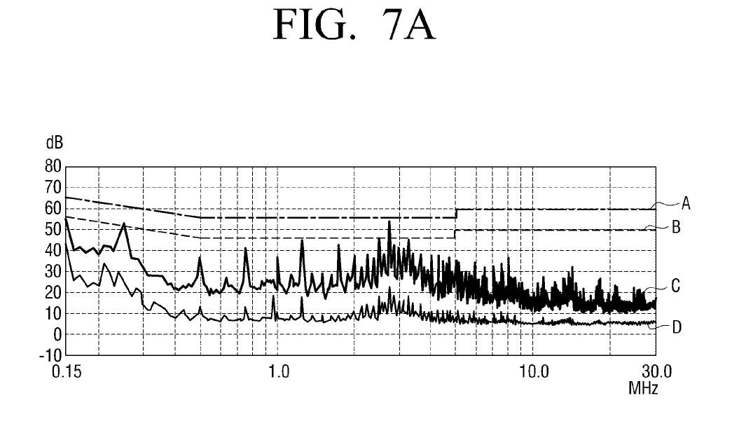

FIG. 6 is a view illustrating another example of a connecting structure of the plasma display apparatus according to an exemplary embodiment. Referring to FIG. 6, the plasma display apparatus 600 is formed so that the driving board 620 is arranged on one side of the chassis base 610. The driving board 620 is attached to one side of the chassis base 610 through at least one screw 630. A variety of patterns may be formed on one side of the driving board 620 and various components are attached thereto. The driving board 620 includes a ground area G.

Yg switching IC 640 is attached to one side of the driving board 620, and a ground pin (P), from among a plurality of pins (terminals) of Yg switching IC 640, is connected to the ground area G of the driving board 620.

A conductive material 660 may be arranged on one side of the driving board 620, and the conductive material 660 is connected to the back cover 670.

The conductive material 660 may contact the ground area G of the driving board 620 and arranged to adjoin the ground area G.

With the plasma display apparatus 600 according to an exemplary embodiment, since the ground area G of the driving board 620 is connected to the back cover 670 via the conductive material 660, conduction noise dissipates and as a result, EMI is reduced.

The difference of the plasma display apparatus 600 of FIG. 6 from that 500 of FIG. 5 is that the heat sink is omitted and the ground area G of the driving board 620 is connected to the back cover 670 via the conductive material 660.

The ‘one side’ in FIG. 6 refers to upper sides of the respective components 610, 620. The component 680 in FIG. 6 may be the AC inlet or SMPS unit. Referring also to FIG. 6, although the exemplary embodiment has been explained mainly with reference to Yg switching IC 640 which has the greatest EMI reduction effect among the various devices, the exemplary embodiment is not limited to this specific example only.

Meanwhile, unlike the examples illustrated in FIGS. 5 and 6, the plasma display apparatus 500, 600 may be formed so that one area of the back cover 570, 670 is directly connected to the ground area G of the driving board 520, 620. The back covers 570, 670 may additionally include a protruding portion and connected directly to the ground area G of the driving board 520, 620 via the protruding portion.

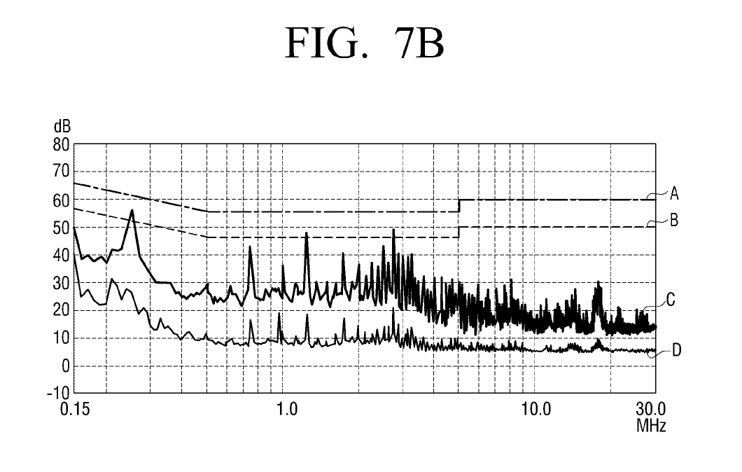

FIG. 7A is a graphical representation of noise generated from a conventional plasma display apparatus, and FIG. 7B is a graphical representation of noise generated from the plasma display apparatus according to an exemplary embodiment.

Referring to FIGS. 7A and 7B, the letter ‘A’ represents an upper limit of the noise peak and ‘B’ represents an upper limit of noise average as the values determined according to the related policy. The letters ‘C’ and ‘D’ respectively represent the noise peak and noise average as the actually measured values.

Referring to FIGS. 7A and 7B, the noise peak C and noise average D of the plasma display apparatus 100, 200, 500, 600 according to an exemplary embodiment are greatly reduced compared to the noise peak C and noise average D measured from a conventional plasma display apparatus.

The plasma display apparatus 100, 200, 500, 600 according to an exemplary embodiment can be manufactured at a greatly reduced cost compared to the conventional plasma display apparatuses.

The foregoing exemplary embodiments and advantages are merely exemplary and are not to be construed as limiting the present inventive concept. The present teaching can be readily applied to other types of apparatuses. Also, the description of the exemplary embodiments of the present inventive concept is intended to be illustrative, and not to limit the scope of the claims, and many alternatives, modifications, and variations will be apparent to those skilled in the art.

What is claimed is:

1. A plasma display apparatus, comprising
a plasma display panel;
a chassis base which supports the plasma display panel;
a driving board which is electrically connected to the plasma display panel and arranged on the chassis base, and which supplies a driving signal to the plasma display panel; and
a back cover which covers the plasma display panel,
wherein the back cover is connected to a ground area of the driving board.

2. The plasma display apparatus of claim 1, further comprising a conductive material attached to one side of the back cover.

3. The plasma display apparatus of claim 2, wherein the back cover is connected to the ground area via the conductive material.

4. The plasma display apparatus of claim 1, further comprising a device unit attached to the driving board to generate the driving signal.

5. The plasma display apparatus of claim 4, further comprising a heat sink arranged in contact with the device unit to transfer heat generated from the device unit to outside.

6. The plasma display apparatus of claim 5, wherein the back cover is connected to the heat sink via the conductive material and the heat sink is connected to the ground area.

7. The plasma display apparatus of claim 1, wherein the driving board is arranged on one side of the chassis base and the plasma display panel is arranged on the other side of the chassis base.

8. The plasma display apparatus of claim 1, wherein the driving board is a Y driving board.

9. The plasma display apparatus of claim 4, wherein the device unit comprises one or more switching devices, and the one or more switching devices comprise a ground pin connected to the ground area of the driving board.

10. The plasma display apparatus of claim 9, wherein the one or more switching devices comprise an integrated circuit (IC).

11. The plasma display apparatus of claim 10, wherein the one or more switching elements comprise a Yg switching IC.

12. The plasma display apparatus of claim 1, further comprising:
an alternating current (AC) inlet which is attached to one side of the chassis base and receives electricity through a power cable; and
a switched mode power supply (SMPS) unit which is attached to one side of the chassis base and which converts the received electricity and provides the converted electricity to the plasma display panel.

13. The plasma display apparatus of claim 12, which dissipates induced sustain noise to the back cover, the chassis base, the AC inlet and the SMPS unit, respectively.

14. A plasma display apparatus comprising:
a chassis base;
a driving board attached to one side of the chassis base, the driving board having a ground area;
a back cover that covers the one side of the chassis base;
a conductive material attached to a portion of a surface of the back cover,
wherein, the ground area of the driving board is electrically connected to the back cover via the conductive material.

15. The plasma display apparatus according to claim 14, further comprising a heat sink attached to the ground area of the driving board, wherein the ground area of the driving board is electrically connected to the back cover via the heat sink and the conductive material.

16. The plasma display apparatus according to claim 14, further comprising an insulating material attached to the surface of the back cover, wherein a part of the insulating material is removed, and a void provided by removal of the part of the insulating material forms the portion of the surface of the back cover to which the conductive material is attached.
